(19) United States
(12) Patent Application Publication
(10) Pub. No.: US 2020/0163247 A1
(43) Pub. Date: May 21, 2020

(54) Modular and Flexible Data Center and Method of Operation

(71) Applicant: SUZHOU A-RACK ENCLOSURE SYSTEMS CO., LTD., Suzhou, Jiangsu (CN)

(72) Inventor: ZhiYong Ding, Suzhou New District (CN)

(21) Appl. No.: 15/860,158

(22) PCT Filed: Sep. 8, 2017
(86) PCT No.: PCT/CN2017/100986

§ 371 Date: Aug. 20, 2019

(30) Foreign Application Priority Data
Jun. 7, 2017 (CN) 201710422318.2

(51) Int. Cl. H05K 7/14; H05K 7/20

(52) U.S. Cl. CPC H05K 7/1497; H05K 7/20736; H05K 7/20745; H05K 7/20827

(57) ABSTRACT

A modular and flexible data center and method of operation enables installing and calibrating the data center during manufacture, such that the data center can be operational at a work site with minimal reconfigurations and optimal flexibility. The data center comprises a container body, a cooling apparatus, a ventilation pipe, and a server. The cooling apparatus is arranged in the container body. The ventilation pipe is arranged above the container body, communicating with the inside of container body via a first communication port and a second communication port, forming a sealed passage with the container body, wherein the first communication port and the cooling apparatus are located at one side of container body; and second communication port is located at the top of container body, away from the cooling apparatus. The server is located inside the container body and between the first communication port and the second communication port.

### CROSS REFERENCE OF RELATED APPLICATIONS

This application claims the benefits of Patent International application no. PCT/CN2017/100986, filed Sep. 8, 2017 and entitled MODULAR DATA CENTER, which provisional application is incorporated by reference herein in its entirety.

### FIELD OF THE INVENTION

The present invention relates generally to a modular and flexible data center and method of operation. More so, the present invention relates to a data center and method for installing and calibrating the data center during manufacture, such that the data center can be operational at a work site with minimal reconfigurations and optimal flexibility; and further reduces long deployment periods, improves cooling environments, and optimizes the flow of cool air through the data center.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

Typically, a data center is a facility used to house computer systems and associated components, such as telecommunications and storage systems. A data center can be a centralized computation facility consisted of a server container body or frame, an air conditioning system, power distribution equipment and uninterrupted power supply equipment, and a building or container body holding these equipment.

Often, the data center includes redundant or backup power supplies, redundant data communications connections, environmental controls, and various security devices. Because of these multiple components working together, modularity and flexibility are key elements in allowing for a data center to grow and change over time. Data center modules are pre-engineered, standardized building blocks that can be easily configured and moved as needed.

It is known in the art that, with rapid development of the electronics industry and communication technologies, the application and management mode of information technologies are gradually transformed from independent and discrete functional resources into an operation mode having the data center as the main operation platform.

In the related art, most data centers use a heat radiation solution of a room-grade cooling mode. Such a traditional data center has high requirements on the site, and can be applied only after the decoration of the machine room is completed and all the required physical structures are available. The period for deploying a traditional data center is very long. Manufacturers of the physical structures are in large number, with numerous crossing procedures.

Further, the data center may include hundreds of racks that hold various types of computer-related modules. When the server racks are installed in the colocation site, a number of interrelated processes are planned out and executed, generally in a relatively short period of time. Examples of such processes include physical layout of the server racks, configuration and wiring of electrical power connections to the server racks, layout of flow-control elements in the cooling system of the data center space, and/or the installation of Internet connectivity wiring and networking systems.

Other proposals have involved the outlay of data centers and cooling the data centers. The problem with these data centers is that such traditional data centers rely exclusively on mechanically cooling the air within the data center, which can lead to excessive power usage and inefficiency. Typically, these data center building processes are completed on-site at the colocation site by technicians, which can be expensive. In addition, because installation at each site is customized to take into account site-specific constraints, i.e., site to site variations in data centers, installation difficulties arise and economies of scale cannot be fully exploited on installations. Thus, a modular and flexible data center that reduces long deployment periods, improves cooling environments, and optimizes the flow of cool air through the data center, is still desired.

### SUMMARY

Illustrative embodiments of the disclosure are generally directed to a modular and flexible data center and method of operation. The data center and method is configured for installing and calibrating the data center during manufacture, such that the data center can be operational at a work site with minimal reconfigurations and optimal flexibility. Further, the data center is configured to reduce long deployment periods, improve cooling environments, and optimize the flow of cool air through the data center.

In some embodiments, the modular and flexible data center may include a container body, a cooling apparatus, a ventilation pipe, and a server. The cooling apparatus is arranged at one side in the container body. The ventilation pipe is arranged above the container body, communicates with the inside of the container body via a first communication port and a second communication port and forms a sealed passage together with the container body.

In this manner, the first communication port and the cooling apparatus are located at one side of the container body, and the second communication port is located at the top inside the container body and away from the cooling apparatus. The server is located inside the container body and between the first communication port and the second communication port.

In one possible aspect of the present disclosure, the first communication port and the second communication port are located at the two ends of the ventilation pipe, respectively.

In another aspect, the cooling apparatus is an air conditioner inner machine comprising a compressor cooling system and a heat pipe heat exchange system.

In another aspect, the compressor cooling system comprises a compressor connected with a controller, the controller being connected with an external temperature sensor and an internal temperature sensor.

In another aspect, the air conditioner inner machine is connected with an air conditioner outer machine located at the outer side of the top of the container body.

In another aspect, the fan of the air conditioner inner machine faces the first communication port.

In another aspect, the fan of the server faces the cooling apparatus.

In another aspect, a cabinet is arranged inside the container body, and the server is placed on the cabinet.

In another aspect, a slide rail is arranged inside the container body, and a slide groove matched with the slide rail is provided to the cabinet and is clamped with the slide rail.

In another aspect, the modular data center further comprises a first lateral door and a second lateral door which are movably arranged on the container body and one of which faces the cooling apparatus.

In one non-limiting embodiment, the modular and flexible data center may be arranged so that the cooling apparatus is arranged at one side in the container body, the ventilation pipe is arranged above the container body, and the ventilation pipe communicates with the inside of the container body via the first and second communication ports such that the ventilation pipe and the container body form a sealed passage.

Further, the server is arranged inside the container body and between the first and second communication ports, such that the low-temperature air discharged from the cooling apparatus is transported from the first communication port to the ventilation pipe, and is discharged from the inside of the ventilation pipe via the second communication port to the side of the container body away from the cooling apparatus.

In this manner, the low-temperature air can completely pass through and sufficiently contact the server, so that better cooling effect of the server is obtained, and the utilization rate of the low-temperature air is improved, optimizing the air flow management. In addition, the modular data center of the present disclosure integrates the server and the cooling apparatus inside the container body, thereby forming a compact structure. After being installed and calibrated in the factory, the data center can be delivered to the work site for direct use and can be used in both indoor and outdoor environments. Further, the time for building a data center is greatly saved, and the cost for building decoration is saved.

One objective of the present invention is to install and calibrate the data center during manufacture, so that it is delivered to the work site with minimal required reconfigurations or adjustments.

Another objective is to provide a data center that is configured for direct use in both indoor and outdoor environments.

Another objective is to enable low-temperature air to completely pass through and sufficiently contact the server in the data center, so as to enhance the cooling effect on the server.

Yet another objective is to enable the data center to have sufficient flexibility in reconfiguring the components, including the container body, the air conditioner inner machine, the ventilation pipe, the server, the air conditioner outer machine, the cabinet, the left door, the right door, the first communication port, the second communication port, the compressor cooling system, and the heat pipe heat exchange system, based on the needs of the work site.

Yet another objective is to provide a compact data center structure.

Yet another objective is to provide an inexpensive to manufacture data center.

Other systems, devices, methods, features, and advantages will be or become apparent to one with skill in the art upon examination of the following drawings and detailed description. It is intended that all such additional systems, methods, features, and advantages be included within this description, be within the scope of the present disclosure, and be protected by the accompanying claims and drawings.

### BRIEF DESCRIPTION OF THE DRAWINGS

The invention will now be described, by way of example, with reference to the accompanying drawings, in which:

FIG. 1 is a schematic structural view of a modular and flexible data center, in accordance with an embodiment of the present invention;

FIG. 2 is a front view of the modular data center, in accordance with an embodiment of the present invention;

FIG. 3 is a left view of the modular data center, in accordance with an embodiment of the present invention;

FIG. 4 is a sectional view along the A-A line in FIG. 3, in accordance with an embodiment of the present invention;

FIG. 5 is a sectional view along the B-B line in FIG. 4, in accordance with an embodiment of the present invention;

FIG. 6 is a sectional view along the C-C line in FIG. 3, in accordance with an embodiment of the present invention;

FIG. 7 is a sectional view along the D-D line in FIG. 3, in accordance with an embodiment of the present invention; and

FIG. 8 is a structural block view of an air conditioner inner machine, in accordance with an embodiment of the present invention.

Like reference numerals refer to like parts throughout the various views of the drawings.

### DETAILED DESCRIPTION OF THE INVENTION

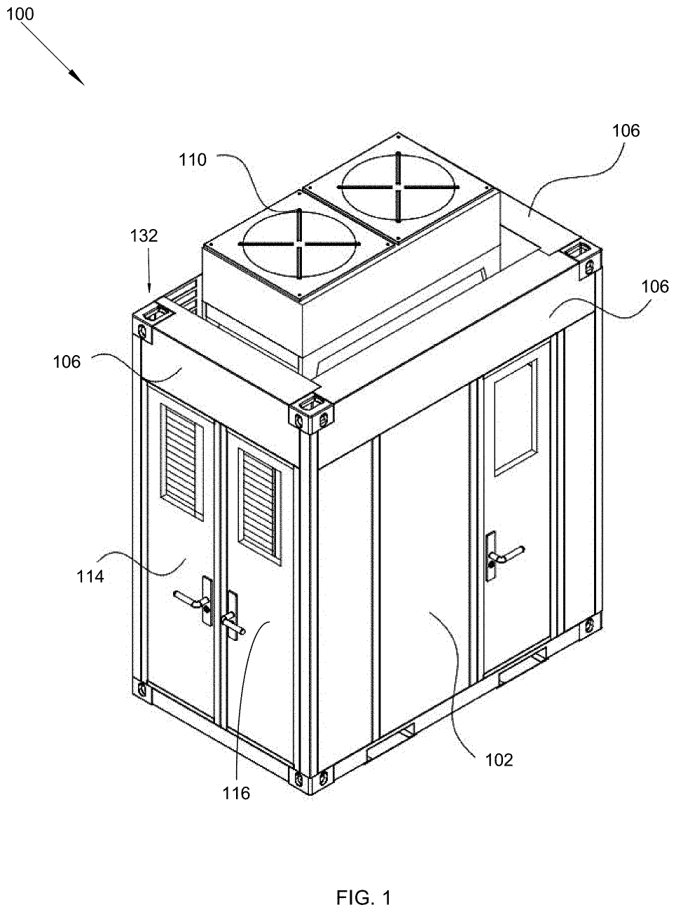

The following detailed description is merely exemplary in nature and is not intended to limit the described embodiments or the application and uses of the described embodiments. As used herein, the word “exemplary” or “illustrative” means “serving as an example, instance, or illustration.” Any implementation described herein as “exemplary” or “illustrative” is not necessarily to be construed as preferred or advantageous over other implementations. All of the implementations described below are exemplary implementations provided to enable persons skilled in the art to make or use the embodiments of the disclosure and are not intended to limit the scope of the disclosure, which is defined by the claims. For purposes of description herein, the terms “upper,” “lower,” “left,” “rear,” “right,” “front,” “vertical,” “horizontal,” and derivatives thereof shall relate to the invention as oriented in FIG. 1. Furthermore, there is no intention to be bound by any expressed or implied theory presented in the preceding technical field, background, brief summary or the following detailed description. It is also to be understood that the specific devices and processes illustrated in the attached drawings, and described in the following specification, are simply exemplary embodiments of the inventive concepts defined in the appended claims. Specific dimensions and other physical characteristics relating to the embodiments disclosed herein are therefore not to be considered as limiting, unless the claims expressly state otherwise.

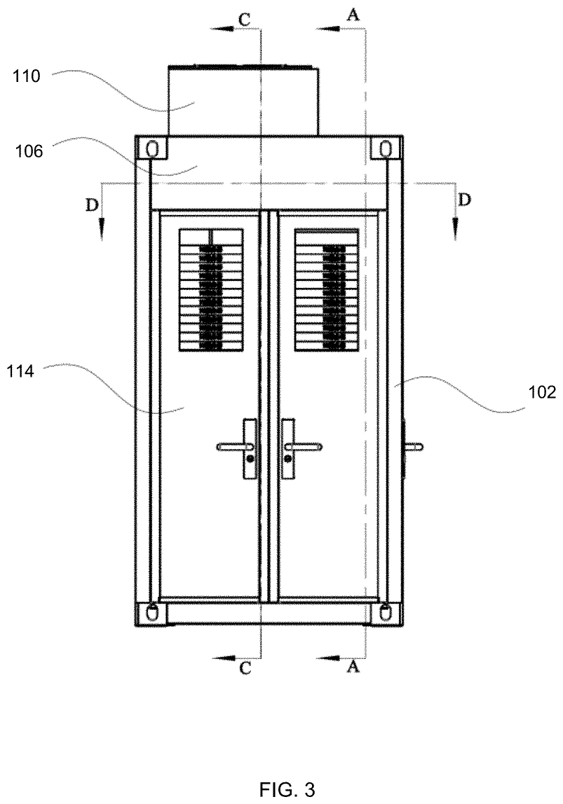

A modular and flexible data center 100 and method of operation is referenced in FIGS. 1-8. As shown in FIG. 1, the data center 100 may include a container body 102 that is defined by a cavity 128 for housing the components of the data center 100. The container body 102 may contain within a cooling apparatus 126, a ventilation pipe 106, and a server 108.

In one non-limiting embodiment, the cooling apparatus 126 is arranged at a first side side 130 of the container body 102. The ventilation pipe 106 is arranged at a point 132 above the container body 102. The ventilation pipe 106 is configured to communicate with the inside of the container body 102 via a first communication port 118 and a second communication port 120.

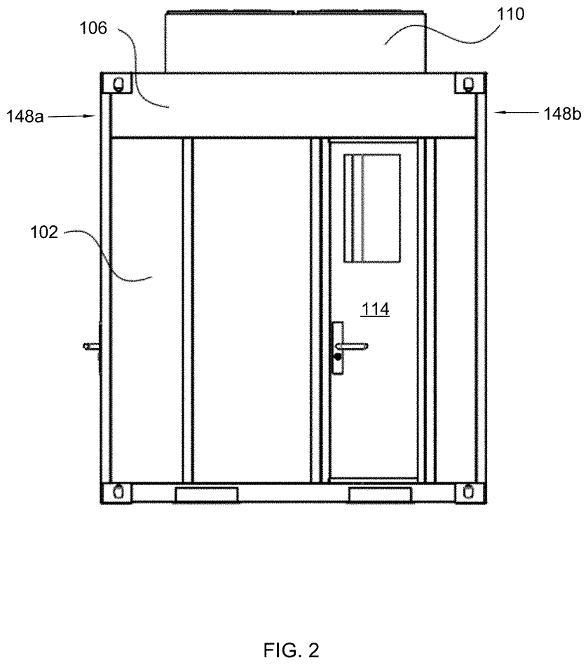

In one non-limiting embodiment shown in FIG. 2, the ventilation pipe 106 is configured to form a sealed passage together with the container body 102. In this manner, the first communication port 118 and the cooling apparatus 126 are located at one side of the container body 102, and the second communication port 120 is located at a top inner side 134 of the container body 102 and away from the cooling apparatus 126. The server 108 is located inside the container body 102 and between the first communication port 118 and the second communication port 120.

In another possible embodiment of the modular and flexible data center, the cooling apparatus 126 is arranged at one side in the container body 102, the ventilation pipe 106 is arranged above the container body 102, and the ventilation pipe 106 communicates with the inside of the container body 102 via the first and second communication ports 118, 120, such that the ventilation pipe 106 and the container body 102 form a sealed passage.

Further, the server 108 is arranged inside the container body 102 and between the first and second communication ports 118, 120, such that the cooled air (i.e., the low-temperature air) discharged from the cooling apparatus 126 is transported from the first communication port 118 to the ventilation pipe 106. The cooled air is also discharged from the inside of the ventilation pipe 106 via the second communication port 120 to the side of the container body 102 away from the cooling apparatus 126.

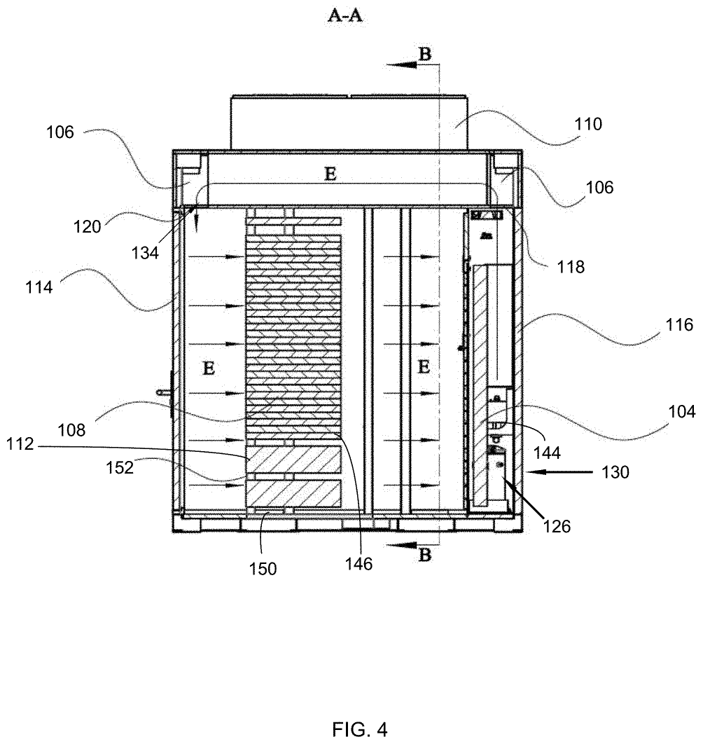

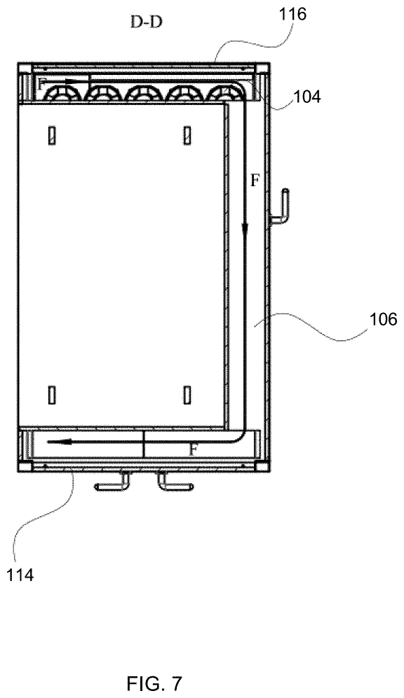

In this manner, the low-temperature air can completely pass through and sufficiently contact the server 108. Thus, the flow direction of the low-temperature air may be the E direction shown in FIG. 4 and the F direction shown in FIG. 7, which results in a more efficient cooling effect of the server 108. Also, the utilization rate of the low-temperature air is improved, optimizing the air flow management.

In addition, the modular and flexible data center 100 is operable to integrate the server 108 and the cooling apparatus 126 inside the container body 102, thereby forming a compact structure. After being installed and calibrated in the factory, the data center can be sent to a work site for direct use and can be used in both indoor and outdoor environments. Further, the time for building a data center 100 is greatly saved, and the cost for building decoration is saved. The low-temperature air refers to the air having a temperature lower than a preset threshold.

In one non-limiting embodiment, the cooling apparatus 126 may be arranged at the middle of the container body 102 and at the center of multiple servers 14. The cooling apparatus 126 may also be arranged in a column manner. In this arrangement, the first communication port 118 corresponds to the cooling apparatus 126 in the vertical direction. Further, the second communication port 120 is located at the top of the container body 102 and at the side of the server 108 away from the cooling apparatus 126.

The first and second communication ports 118, 120 are arranged at the two ends 148a, 148b of the ventilation pipe 106, respectively. Thus, the low-temperature air is transported uni-directionally in a single passage, and is effectively prevented from absorbing heat during the transportation process, thereby improving the utilization rate of the low-temperature air for cooling the server 108.

In one non-limiting embodiment, the cooling apparatus comprises an air conditioner inner machine 104. The air conditioner inner machine 104 may include a compressor cooling system 122 and a heat pipe heat exchange system 124. The compressor cooling system 122 comprises a compressor 136 connected with a controller 138. The controller 138 is operationally connected to an external temperature sensor 140 and an internal temperature sensor 142.

In some embodiments, the external and internal temperature sensors 140, 142 can measure the temperatures inside and outside the container body 102, and transmit the acquired temperature data to the controller 138. When the measured temperature difference is larger than or equal to a preset temperature, the controller 138 controls the compressor to operate. Thus, the compressor cooling system 122 and the heat pipe heat exchange system 124 can operate simultaneously, whereby cooling of the server 108 inside the container body 102 can be performed effectively.

Thus, when the measured temperature difference is smaller than the preset temperature, cooling of the server 108 can be realized by only operating the heat pipe heat exchange system 124; at this time, the controller will not issue operation commands to the compressor, thereby effectively reducing energy consumption. By integrating the compressor cooling system 122 and the heat pipe heat exchange system 124, the cooling apparatus 126 can select a required system according to the preset temperature so as to reduce energy consumption.

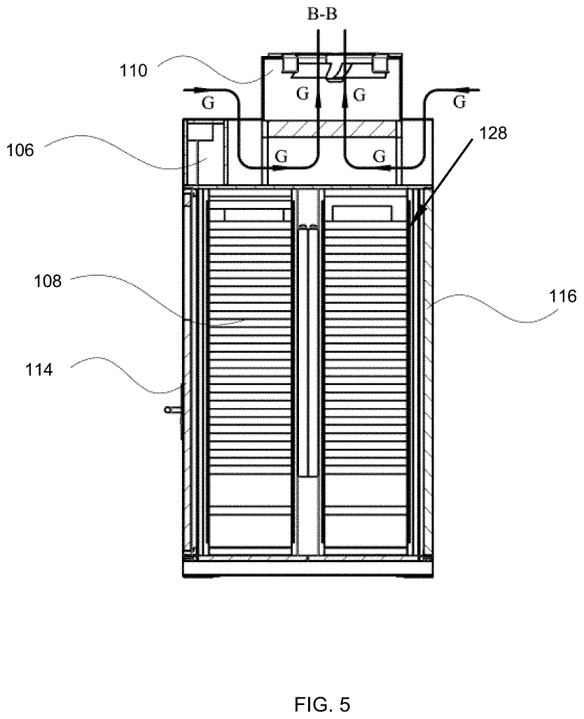

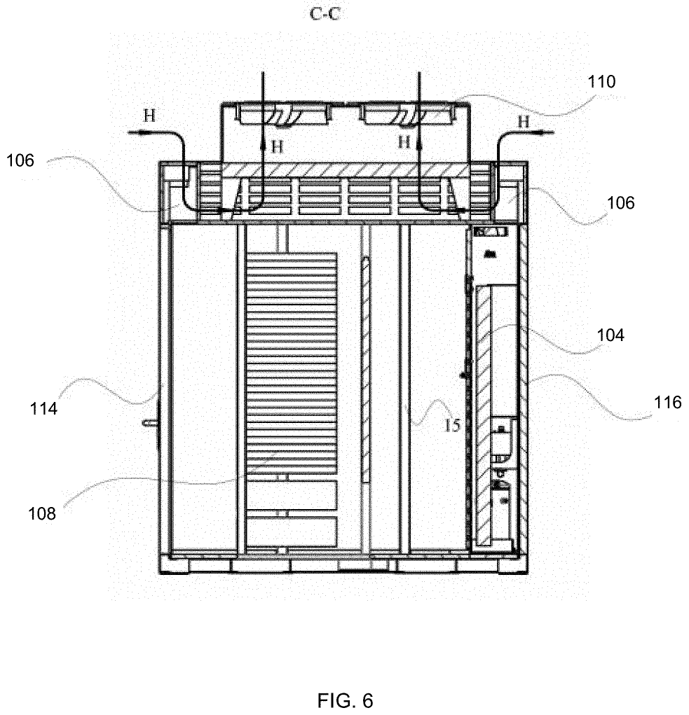

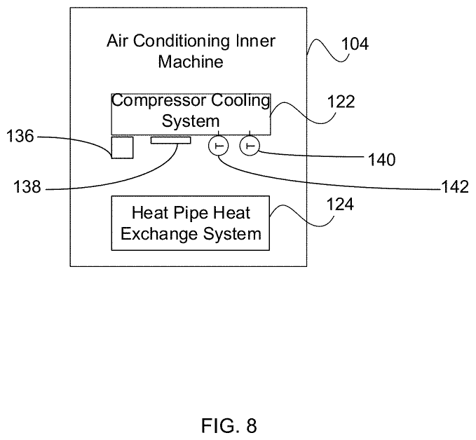

FIG. 8 illustrates a structural block view of an air conditioner inner machine 104. The air conditioner inner machine 104 is connected with an air conditioner outer machine 110 located at the top of the container body 102. The air flow direction in the air conditioner outer machine 110 is the G direction in FIG. 5 and the H direction in FIG. 6. The air conditioner outer machine 110 is cooled naturally by ambient air.

The fan of the air conditioner inner machine 104 comprises a fan 144. The fan 144 of the air conditioner inner machine 104 faces the first communication port 118. Optionally, the air discharging port of the fan is close to the first communication port 118, so that the low-temperature air generated in the air conditioner inner machine 104 can be discharged to the ventilation pipe 106 directly.

In this manner, loss of the low-temperature air during the transportation process is reduced, and the utilization rate of the low-temperature air for cooling the server 108 is improved effectively. Optionally, the air conditioner inner machine 104 is a windwall air conditioner inner machine, which occupies less space, saves energy, and can effectively radiate heat using the wind passage walls.

The server 108 comprises a server fan 146. The fan server 146 faces the cooling apparatus 126, so that the low-temperature air at the side of the server 108 away from the cooling apparatus 126 can be effectively sucked into the server 108, thereby increasing the flow rate of the low-temperature air and improving the utilization rate of the low-temperature air for cooling the server 108.

In yet another possible embodiment, a cabinet 112 is arranged inside the container body 102. And the server 108 is placed on the cabinet 112. A slide rail 150 is arranged inside the container body 102. A slide groove 152 corresponding with the slide rail 150 is provided to the cabinet 112 and is clamped with the slide rail. In this way, installation, pickup and maintenance of the server 108 can be made convenient and quick.

The modular and flexible data center 100 may further comprise a left door 114 and a right door 116, which are movably arranged on the container body 102 and one of which faces the cooling apparatus 126. When the cooling apparatus 126 has a failure, the cooling apparatus 126 can be maintained by opening the right door 114 or the right door 116, which is convenient, quick and easy to operate.

It is significant to note that there are numerous industrial applications of the data center 100. For example, the low-temperature air can completely pass through and sufficiently contact the server, so that better cooling effect of the server is obtained, and the utilization rate of the low-temperature air is improved; whereby air flow management is optimized. In addition, the modular data center has a compact structure. After being installed and calibrated in the factory, the data center can be sent to the site for direct use and can be used in both indoor and outdoor environments. Further, the time for building a data center is greatly saved, and the cost for building decoration is saved.

These and other advantages of the invention will be further understood and appreciated by those skilled in the art by reference to the following written specification, claims and appended drawings.

Because many modifications, variations, and changes in detail can be made to the described preferred embodiments of the invention, it is intended that all matters in the foregoing description and shown in the accompanying drawings be interpreted as illustrative and not in a limiting sense. Thus, the scope of the invention should be determined by the appended claims and their legal equivalence.

What is claimed is:

1-20. (canceled)

21. A modular and flexible data center, comprising:
a container body;
a cooling apparatus arranged at one side in the container body;
a ventilation pipe arranged above the container body, wherein the ventilation pipe communicates with the inside of the container body via a first communication port and a second communication port, and the ventilation pipe forms a sealed passage together with the container body, wherein the first communication port and the cooling apparatus are located at one side of the container body, and the second communication port is located at the top inside the container body and away from the cooling apparatus; and
a server located inside the container body and between the first communication port and the second communication port.

22. The modular and flexible data center according to claim 21, wherein the first communication port and the second communication port are located at the two ends of the ventilation pipe, respectively.

23. The modular and flexible data center according to claim 22, wherein the cooling apparatus is an air conditioner inner machine comprising a compressor cooling system and a heat pipe heat exchange system.

24. The modular and flexible data center according to claim 23, wherein the compressor cooling system comprises a compressor connected with a controller, wherein the controller is connected with an external temperature sensor and an internal temperature sensor.

25. The modular data center according to claim 23, wherein the air conditioner inner machine is connected with an air conditioner outer machine located at the outer side of the top of the container body.

26. The modular and flexible data center according to claim 23, wherein the fan of the air conditioner inner machine faces the first communication port.

27. The modular and flexible data center according to claim 26, wherein the fan of the server faces the cooling apparatus.

28. The modular and flexible data center according to claim 26, wherein a cabinet is arranged inside the container body, and the server is placed on the cabinet.

29. The modular and flexible data center according to claim 28, wherein a slide rail is arranged inside the container body, and a slide groove matched with the slide rail is provided to the cabinet and is clamped with the slide rail.

30. The modular and flexible data center according to claim 26, further comprising a first lateral door and a second lateral door, wherein the first lateral door and the second lateral door are movably arranged on the container body and one of which faces the cooling apparatus.
